(19) United States
(12) Patent Application Publication
(10) Pub. No.: US 2014/0273487 A1
(43) Pub. Date: Sep. 18, 2014

(54) PULSED DC PLASMA ETCHING PROCESS AND APPARATUS

(71) Applicant: Applied Materials, Inc., Santa Clara, CA (US)

(72) Inventors: Subhash Deshmukh, Livermore, CA (US); He Ren, San Jose, CA (US); Jingjing Liu, Milpitas, CA (US)

(21) Appl. No.: 14/200,779

(22) Filed: Mar. 7, 2014

Related U.S. Application Data
(60) Provisional application No. 61/779,296, filed on Mar. 13, 2013.

(51) Int. Cl. H01L 21/3065; H01L 21/67

(52) U.S. Cl. CPC H01L 21/3065; H01L 21/67069
USPC 438/714; 156/345.43

(57) ABSTRACT

In one aspect, a plasma etching apparatus is disclosed. The plasma etching apparatus includes a chamber body having a process chamber adapted to receive a substrate, an RF source coupled to an RF electrode, a pedestal located in the processing chamber and adapted to support a substrate, a plurality of conductive pins adapted to contact and support the substrate during processing, and a DC bias source electrically coupled to the plurality of conductive pins. Etching methods are provided, as are numerous other aspects.

### RELATED APPLICATIONS

The present application claims priority to U.S. Provisional Application 61/779,296 filed Mar. 13, 2013, and entitled “PULSED DC PLASMA ETCHING PROCESS AND APPARATUS” (Attorney Docket No. 17758/L), which is hereby incorporated herein for all purposes.

### FIELD

The present invention relates generally to semiconductor device manufacturing, and more particularly to plasma processes and apparatus.

### BACKGROUND

Within semiconductor substrate manufacturing, a plasma etching process may be used to remove one or material layers or films, or form patterns or the like on a substrate (e.g., form a patterned silicon wafer). As critical dimensions keep shrinking, it becomes desirable to more tightly control the etching process in order to achieve good trench profile, within wafer uniformity, and achieve more precise Critical Dimension (CD) control.

One prior etching process uses a pulsing of a plasma radio-frequency (RF) source. RF source control may lead to relatively separate control of ion (reactive etchant) density and energy distribution, so as to widen the process window. The pulsing may be synchronized to provide improved process control in RF positive/negative cycles. However, RF pulsing techniques may have drawbacks in terms of complicated implementation and difficulty in reaching precise control.

In other implementations, a DC bias may be applied to a pedestal to control etchant energy. However, such DC biased processes suffer from the disadvantage of a narrow process window.

Accordingly, improved etching methods and apparatus are desired for improved CD control.

### SUMMARY

In a first aspect, a plasma etching apparatus is provided. The plasma etching apparatus includes a chamber body having a process chamber adapted to receive a substrate, an RF electrode coupled to a RF bias source, a pedestal located in the processing chamber and adapted to support a substrate, a plurality of conductive pins adapted to contact and support the substrate during processing, and a pulsed DC bias source coupled to the plurality of conductive pins.

In another aspect, a plasma etching method is provided. The plasma etching method includes providing the substrate within a process chamber, providing a process gas to the process chamber, exposing the process gas in the process chamber to RF pulses, and providing DC bias pulses to the substrate through conductive pins in electrically conductive contact with the substrate.

Other features and aspects of the present invention will become more fully apparent from the following detailed description of example embodiments, the appended claims, and the accompanying drawings.

### BRIEF DESCRIPTION OF THE DRAWINGS

FIG. 1 illustrates a partial side plan view of a substrate etching apparatus according to embodiments.

FIG. 2A illustrates a partial top view of a DC bias conductor pin assembly illustrating possible positions of the DC bias conductor pins according to embodiments.

FIG. 2B illustrates a side view of a DC bias conductor pin assembly according to embodiments.

FIG. 3 illustrates a graphical plot of an RF Pulse and DC bias pulse relative to a master clock pulse according to embodiments.

FIG. 4 illustrates a flowchart of a plasma etching method according to embodiments.

### DETAILED DESCRIPTION

Embodiments described herein relate to apparatus and methods adapted to etch a surface (e.g., one or more layers) of a substrate. In particular, improved etching methods adapted to provide metal etching are provided in some embodiments. For example, the method and system are useful for etching materials in semiconductor processing, and, in particular, for processing feature sizes on substrates of 20 nm or less.

Embodiments of the invention include a combination of a RF pulse source and a pulsed DC bias applied to the substrate. The pulsed DC bias is provided through conductive DC bias pins that are provided in direct electrical contact with the substrate. The conductive DC bias pins are part of a DC bias conductor assembly that lifts the substrate and also provides DC bias pulsing to the substrate to accomplish improved substrate etching.

These and other aspects of embodiments of the invention are described below with reference to FIGS. 1-4 herein.

FIG. 1 illustrates a partially cross-sectioned side view of a substrate etching apparatus 100 and components thereof. The substrate etching apparatus 100 is adapted to couple to a mainframe section 104 and is configured and adapted to receive a substrate 102 within a process chamber 105 formed in a body 106 of the substrate etching apparatus 100 and perform an etching process thereon. The substrate 102 (shown dotted) may be any suitable substrate to be etched, such as a doped or un-doped silicon substrate, a III-V compound substrate, a silicon germanium (SiGe) substrate, an epi-substrate, a silicon-on-insulator (SOI) substrate, a display substrate such as a liquid crystal display (LCD) substrate, a plasma display substrate, an electro luminescence (EL) lamp display substrate, a light emitting diode (LED) substrate, a solar cell array substrate, solar panel substrate, or the like. Other substrates may be processed as well. In some embodiments, the substrate 102 may be a semiconductor wafer having a pattern or a mask formed thereon.

In some embodiments, the substrate 102 may have one or more layers disposed thereon. The one or more layers may be deposited in any suitable manner, such as by electroplating, chemical vapor deposition (CVD), physical vapor deposition (PVD), atomic layer deposition (ALD), or the like. The one or more layers may be any layers suitable for a particular device being fabricated.

For example, in some embodiments, the one or more layers may comprise one or more dielectric layers. In such embodiments, the one or more dielectric layers may comprise silicon oxide (SiO₂), silicon nitride (SiN), a low-k or high-k material, or the like, As used herein, low-k materials have a dielectric constant that is less than about that of silicon oxide (SiO₂). Accordingly, high-k materials have a dielectric constant greater than silicon oxide. In some embodiments, where the dielectric layer comprises a low-k material, the low-k material my be a carbon-doped dielectric material such as carbon-doped silicon oxide (SiOC), an organic polymer (such as polyimide, parylene, or the like), organic doped silicon glass (OSG), fluorine doped silicon glass (FSG), or the like. In embodiments, the dielectric layer is a high-k material such as silicon oxide (SiO₂), hafnium oxide (HfO₂), zirconium oxide (ZrO₂), hafnium silicate (HfSiO), or aluminum oxide (Al₂O₃), or the like. In some embodiments, the one or more layers may comprise one or more layers of a conductive material, for example such as a metal. In such embodiments, the metal may comprise copper (Cu), aluminum (Al), tungsten (W), titanium (Ti), alloys thereof, combinations thereof, or the like.

In some embodiments, the substrate 102 may include a patterned mask layer, which may define one or more features to be etched on the substrate 102. In some embodiments, the one or more features to be etched may be high aspect ratio features, wherein the one or more features have an aspect ratio of create than about 10:1. The patterned mask layer may be any suitable mask layer such as a hard mask, photoresist laver, or combinations thereof. Any suitable mask layer composition may be used. The mask layer may have any suitable shape capable of providing an adequate template for defining the features to be etched into the one or more layers of the substrate 102. For example, in some embodiments, the patterned mask layer may be formed via an etching process. In some embodiments, the patterned mask layer may be utilized to define advanced or very small features, such as very small node devices (e.g., features of about 20 nm or smaller nodes). The patterned mask layer may be formed via any suitable technique, such as a spacer mask patterning technique.

The substrate etching apparatus 100 further includes a lid 107 comprising a portion of the body 106 that may be removable to service the process chamber 105. The body 106 includes a slit opening 108 that allows substrates 102 to be inserted into the process chamber 105 from a transfer chamber 111 by an end effector 109 of a robot (not shown) in order to undergo an etching process. The end effector 109 may remove the substrate 102 from the process chamber 105 following completion of the etching process thereat. The slit opening 108 may be sealed by a slit valve apparatus 110 during the process. Slit valve apparatus 110 may have a slit valve door covering the opening 108. Slit valve apparatus 110 may include any suitable slit valve construction, such as taught in U.S. Pat. Nos. 6,173,938; 6,347,918; and 7,007,919. In some embodiments, the slit valve 110 may be an L-motion slit valve, for example.

The substrate etching apparatus 100 also includes a gas supply assembly 112 configured and adapted to provide a process gas 113 into the process chamber 105. Gas supply assembly 112 may include a process gas source 114, one or more flow control devices, such as one or more mass flow controllers 116 and/or one or more flow control valves 118. The process gas source 114 may comprise one or more pressurized vessels containing one or more process gases.

In the depicted embodiment, a first process gas 113 may be provided into a pre-chamber 120 through first inlet 122 formed in a side wall of the body 106. A showerhead 124 having a plurality of passages formed therein may separate the pre-chamber 120 from the process chamber 105 and functions to evenly distribute the first process gas 113 as the first process gas 113 flows into the process chamber 105. A second gas may be introduced directly into the process chamber 105 at a second inlet 123 at times. The second process gas may function to assist or enhance the process by synergistically reacting with the first gas 113, and to help clean the process chamber 105.

The first process gas 113 may comprise any gas or gases suitable to form plasma in order to etch the one or more layers and/or the substrate 102. For example, in some embodiments the first process gas or gases may comprise at least one of a hydrofluorocarbon (CxHyFz), a halogen containing gas such as chlorine (Cl₂) or bromine (Br₂), oxygen (O₂), nitrogen trifluoride (NF₃), sulfur hexafluoride (SF₆), hydrogen gas (H₂), or the like. The first process gas 113 may be provided at any suitable low rate, for example, such as about 10 sccm to about 1,000 sccm. Other suitable flow rates may be used.

Optionally, a carrier gas may be provided with or act as the first process gas 113. The carrier gas may be any one or more inert gases, such as nitrogen (N₂), helium (He), argon (Ar), xenon (Xe), or the like. In some embodiments, the carrier gas may be provided at flow rate of about 10 sccm to about 1,000 sccm. Other suitable flow rates may be used.

In the depicted embodiment, an RF electrode 126 resides in the pre-chamber 120 and is operable therein at a first frequency and is adapted to produce plasma in the processing chamber 105. The RF electrode 126 may comprise a conductive metal plate for voltage upholding and ceramic isolation pieces, as is conventional. RF electrode 126 is electrically coupled to, and driven by, an RF source 127. RF source 127 is driven responsive to signals from an RF pulse generator 128, which will be explained further below.

The substrate etching apparatus 100 also includes a pedestal 129 located in the process chamber 105 and adapted to support the substrate 102 at times. The pedestal 129 is stationarily mounted to the body 106. Pedestal 129 may include a heater 130 (FIG. 2B) operable to heat the substrate 102 prior to starting the etching process. Heater 130 may be a suitable heater, such as a resistive heater and may be operable to heat the pedestal 129 to a temperature of between about 30 degrees C. to about 250 degrees C., or more, for example. Other temperatures may be used. During processing, a plurality of conductive pins 131 (several labeled) are configured and adapted to lift, contact, and support the substrate 102 at a defined height within the process chamber 105 during the etching process, as shown in FIG. 1.

The plurality of conductive pins 131 may be part of a conductive pin assembly 132 comprising a base 133 with the conductive pins 131 extending therefrom. The number of conductive pins 131 may be more than three. In some embodiments, the number of conductive pins 131 may be five or more, or even 9 or more, for example. More or less numbers of conductive pins 131 may be used. Conductive pins 131 may be made of a conductive metal, such as W/Ti alloy, and may have a length of between about 30 mm and about 60 mm, and a diameter of between about 5 mm and about 15 mm. Other dimensions and materials may be used. The substrate 102 should be placed by the conductive pins 131 within between about 10 mm and about 50 mm from the showerhead 124 during plasma processing. The electrical connection using conductive pins 131 during processing may avoid charge-induced ramp-up/ramp-down during pulsing.

FIGS. 2A and 2B illustrate a conductive pin assembly 132 and the electrical connections thereto. An actuator 134 coupled to the base 133 may be actuated to lift or lower the conductive pins 131 in the vertical direction, and thus lift or lower the substrate 102 at various times during the processing. First and second electrical cables 136, 138 electrically connect to the conductive pin assembly 132. Base 133 may be an electrically conductive metal, such as steel, copper, or aluminum. In the depicted embodiment, a DC bias source 140 is electrically coupled to the plurality of conductive pins 131 through the electrical cable 136 being coupled to an electrically conductive base 133. A DC pulse generator 142 (FIG. 1) provides a pulsed drive signal to the DC bias source 140 and a pulse DC bias is provided to the conductive pins 131. In order to insulate the actuator 134, the connection to the base 133 may comprise an insulating connector 144.

The pedestal 129 may comprise a ceramic material such as glass ceramic or metal carbide having a plurality of holes 145 formed therein. The conductive pins 131 are received in, and pass through, the holes 145 and are reciprocal therein responsive to actuation of the actuator 134. The conductive pins 131 should extend through the holes 145 by between about 10 mm and about 30 mm, for example. Other extending values may be used. The heater 130, such as a resistive heater, may be received underneath the pedestal 129 or otherwise thermally coupled thereto, and is configured and operable to heat the pedestal 129 via power supplied from the heater control 148 by the second cable 138.

In operation, conductive pins 131 may be first raised to receive a substrate 102 that is inserted through the opening 108 on the end effector 109 of a robot housed in the transfer chamber 111. The slit valve apparatus 110 may be closed and the conductive pins 131 may be lowered by the actuator 134 to bring the substrate 102 into intimate thermal contact with the pedestal 129, which may be heated. A pump 149, such as a vacuum pump may pump down the process chamber 105 to a suitable vacuum level for etching. Base vacuum level may be maintained at a pressure of below about 1×10-2 mTorr, whereas processing pressure may be maintained in the range of about sub 10 mTorr to about sub Torr level. Other vacuum pressures may be used.

After the substrate 102 is sufficiently heated and a suitable chamber pressure is provided, the actuator 134 may cause the conductor pins 131 to raise and contact the substrate 102 and raise the substrate 102 to a predetermined location within the process chamber 105. The first process gas 113 may be flowed into the inlet 122 from the process gas source 114 and an RF pulse is applied to the RF electrode 126. Similarly, a DC bias pulse is applied to the conducting pins 131 from the DC bias source 140.

In the depicted embodiment shown in FIG. 3, the various pulse traces 300 of the master clock pulse 350, RF pulse 352 applied to the RF electrode 126, and the DC bias pulse 355 applied to the conductive pins 131 are each shown against the same time axis. In some embodiments, the RF pulse generator 128 and the DC pulse generator 142 may be synchronized by a master clock 155 and each may be voltage signals. Further, both the RF pulse generator 128 and the DC pulse generator 142 may have a time delay instituted relative to the master clock signal 350 produced by the master clock 155. An RF delay 358 and DC bias delay 360 (e.g., delay 1 and delay 2, respectively) may be separately adjustable, and may be determined and set by process control 156 based upon experimental etching runs. The frequency of each of the RF pulse 352 and the DC bias pulse 354 may be adjusted by adjusting the frequency of the master clock 155, for example. A frequency multiplier may be used. Thus, in some embodiments, the frequency of the RF pulse 352 may be different than (e.g., any multiple of) the DC bias Pulse 354. For example, the RF pulse 352 may be operated at twice the DC bias pulse 354 in some embodiments. Other multiples may be used.

The DC bias pulse 354 may comprise square wave pulses having a frequency of between about 1 MHz to about 60 MHz, for example. The frequency of the DC bias pulses 354 may be varied in some embodiments. The DC bias pulse 354 may have a pulsing duty cycle from about 10% to about 90%, for example. Pulsing duty cycle is defined herein as the fraction of on time (at peak power) over one full period. The DC bias pulse 354 may have a peak power of between about 10W to about 2,000W, for example. In some embodiments, the DC bias pulse 354 may be pulsed from a positive voltage (in the on condition) to a negative voltage (in the off condition). In other embodiments, the DC bias pulse 354 may be a positive voltage with a superimposed pulsed voltage, but the applied voltage to the conductive pins 131 is always positive, with the peak voltage in the On condition and a lesser on the Off condition. The peak amplitude of the DC bias pulse 354 may be modulated per pulse, in any desired pattern, or randomly.

The applied RF pulse 352 may have a frequency of between about 2 MHz and about 120 MHz, for example. The RF pulse 354 may have an applied peak RF power between about 100W to about 3,000W. A frequency of the RF pulses 352 may be varied in some embodiments. In other embodiments, a frequency of the RF pulses 352 and the frequency of the DC bias pulses 354 are varied. The bias delay 360 from the clock signal 350 may be adjusted to provide a period of time for each pulse after the RF returns to the off condition to allow for a residue reaction with any process residue remaining after the RIE (Reactive Ion Etching) phase. The RF delay 358 and bias delay 360 may be adjusted between 1% and about 80% of the master clock period. Other delays may be used.

To facilitate control of the etching process, controller 162 may be coupled to the various apparatus components. The controller 162 may be provided in the form of a general-purpose computer processor or micro-processor that may be used for controlling various functions. The controller 162 may include processor and memory such as random access memory (RAM), read only memory (ROM), floppy disk, hard disk, or any other form of digital storage, either local or remote. Various electrical circuits may embody the process control 156, master clock 155, RF pulse generator 128, DC pulse generator 142, as well as RF source 127 and DC Bias source 140. These circuits may include cache, power supplies, clock circuits, amplifiers, modulators, comparators, filters, signal generators, an input/output circuitry and subsystems, and the like.

The inventive methods disclosed herein may generally be stored in the memo- or computer-readable medium as a software routine that when executed by the processor, causes the process chamber 105 to perform the etching process on the substrate 102 according to embodiments of the present invention.

FIG. 4 illustrates a plasma etching method 400 adapted to etch a substrate (e.g., substrate 102). The plasma etching method 400 includes, in 402, providing the substrate within a process chamber (e.g., process chamber 105), and providing a process gas (e.g., process gas 113) to the process chamber in 404. The method 400 further includes, in 406, exposing the process gas in the process chamber to RF pulses (e.g., RF pulses 352), and, in 408, providing DC bias pulses (e.g., DC bias pulses 354) to the substrate through conductive pins (e.g., conductive pins 131) in electrically conductive contact with the substrate.

From the applied RE pulses 352 and DC bias pulses 354, plasma is formed from the process gas 113. Generally, to form the plasma, the process gas 113 may be ignited into plasma by coupling RF power from the RF source 127 at a suitable frequency to the process gas 113 within the process chamber 105 under suitable conditions to establish the plasma. In some embodiments, the plasma power source may be provided an RF electrode 126 that is disposed within the pre-chamber 120 or process chamber 105. Optionally, the RF power source may be provided by or more RF induction coils that are disposed within or surrounding the body 106 and act as an RF electrode. In other embodiment, the RF source may be a remote source, such as is taught in U.S. Pat. No. 7,658,802 to Fu et al. Other suitable resources may be used to produce the RF pulses.

The apparatus and method described herein is particularly effective for removing non-volatile residues that form during the etching process itself. In accordance with an aspect of the invention, the DC power damping location is controlled by the pulsing frequency. At a low frequency range (e.g. <10 MHz, depending on relation between ion transit time and pulsing frequency) DC bias power is coupled to the plasma sheath, which increases the ion etchant energy. At a higher frequency range (e.g., >10 MHz), power coupling contributes to bulk plasma for improved plasma density and potential control. The etchant energy may be further controlled by duty cycle and DC bias power input. Accordingly, etch rate and trench profile shape may be improved.

Bias amplitude modulation may be provided to separate the desired surface reaction (etching) versus undesired processes. During the “DC bias-On” periods of DC bias pulses 354, reactive etchants gain energy and perform controlled etching within the duty cycle. For “DC bias-Off” periods, plasma is transferred to new equilibrium for etch residue purge and reactive etchant cycling. DC bias may be modulated between about 10% and about 100% of the peak power.

The DC bias pulses 354 can be applied for either dielectric and/or conductive materials/substrate etching processes with requirements of broad process window and relatively precise specification control, including etch depths, CD control and uniformity, and trench profile. The present method and apparatus may be useful for features having dimensions of 20 nm or less (e.g., 20 nm technology node and beyond.)

In particular, DC bias pulsing may be significantly beneficial to etch processes, during which non-volatile byproducts are developed. For example, such etching processes include copper etch with CuX, where X═Cl, Br, and the like, and/or CuO residues, TiN etch with TiF, TiOF, TiOx residues, SiN etch with SiON residue, or oxidized layers, Ru etch and related residue, and the like. The non-volatile byproducts (residues) can be more selectively and efficiently removed by embodiments of the present method and using the apparatus 100 described herein.

Additional process parameters may be utilized to promote plasma ignition and plasma stability. For example, in some embodiments, the process chamber 105 may be heated by suitable heater elements (not shown) in thermal contact with the body 106, and maintained at a temperature of between about 60 to about 100 degrees Celsius during plasma ignition.

Accordingly, while the present invention has been disclosed in connection with example embodiments thereof, it should be understood that other embodiments may fall within the scope of the invention, as defined by the following claims.

The invention claimed is:

1. A plasma etching apparatus, comprising:
a chamber body having a process chamber adapted to receive a substrate;
an RF source coupled to an RF electrode;
a pedestal located in the processing chamber and adapted to support a substrate;
a plurality of conductive pins adapted to contact and support the substrate during processing; and
a DC bias source coupled to the plurality of conductive pins.

2. The plasma etching apparatus of claim 1, wherein the plurality of conductive pins pass through the pedestal, and the pedestal is stationary.

3. The plasma etching apparatus of claim 1, wherein the number of pins comprises more than three.

4. The plasma etching apparatus of claim 1, wherein the pedestal comprises a heater.

5. The plasma etching apparatus of claim 1, wherein the pedestal comprises a ceramic having holes receiving the plurality of conductive pins.

6. The plasma etching apparatus of claim 1, comprising a controller having
an RF pulse generator coupled to the RF source and adapted to produce an RF pulse; and
a DC pulse generator coupled to the DC bias source and adapted to produce a DC bias pulse.

7. The plasma etching apparatus of claim 6, wherein each of the RF pulse generator and the DC pulse generator are synchronized by a master clock.

8. The plasma etching apparatus of claim 6, wherein each of the RF pulse generator and the DC pulse generator may include a delay relative to a master clock.

9. The plasma etching apparatus of claim 6, wherein the DC pulse generator is driven at a frequency of between about 1 MHz and about 60 MHz.

10. The plasma etching apparatus of claim 6, wherein the RF pulse generator is driven at a frequency of between about 2 MHz and about 120 MHz.

11. The plasma etching apparatus of claim 6, wherein the DC pulse generator produces a DC bias pulse having a duty cycle of between 10% and 90%.

12. The plasma etching apparatus of claim 6, wherein the DC bias source produces a bias power of between about 10W and about 2,000W.

13. The plasma etching apparatus of claim 6, wherein the DC pulse generator comprises amplitude modulation.

14. A plasma etching method, comprising:
providing the substrate within a process chamber;
providing a process gas to the process chamber;
exposing the process gas in the process chamber to RF pulses; and
providing DC bias pulses to the substrate through conductive pins in electrically conductive contact with the substrate.

15. The method of claim 14, comprising varying a frequency of the DC bias pulses.

16. The method of claim 14, comprising varying a frequency of the RF pulses and the frequency of the DC bias pulses.

17. The method of claim 14, comprising varying a duty cycle the DC bias pulses.

18. The method of claim 14, comprising modulating amplitude of the DC bias pulses.

19. The method of claim 14, comprising removing copper residue from the substrate.

20. The method of claim 14, wherein the DC bias pulses have a bias power of between about 10W and about 2,000W.
